(19) United States
(12) Patent Application Publication
(10) Pub. No.: US 2017/0018730 A1
(43) Pub. Date: Jan. 19, 2017

(54) Organic Optoelectronic Device and Method of Manufacturing an Organic Optoelectronic Device

(71) Applicant: OSRAM OLED GmbH, Regensburg (DE)

(72) Inventors: Michael Popp, Freising (DE); Philipp Schwamb, Regensburg (DE); Richard Baisl, Regensburg (DE)

(21) Appl. No.: 15/211,987

(22) Filed: Jul. 15, 2016

(30) Foreign Application Priority Data
Jul. 16, 2015 (DE) 10 2015 111 564.6

(51) Int. Cl. H01L 51/52

(52) U.S. Cl. CPC H01L 51/5209

(57) ABSTRACT

In at least one embodiment, an organic optoelectronic component, which is preferably an organic light emitting diode, includes a first electrode layer, a second electrode layer and an organic layer sequence situated between the electrode layers. Furthermore, the component includes a light-transmissive current confinement layer, which is fitted over the whole area between the first electrode layer and the organic layer sequence, such that the organic layer sequence is spaced apart from the first electrode layer. The current confinement layer is produced continuously from a common starting material and is structured by treatment and/or by action of temperature into at least one conductive region having a high electrical conductivity and into at least one insulating region having a low electrical conductivity. These electrical conductivities differ from one another by at least a factor of 10.

This patent application claims the priority of German patent application 10 2015 111 564.6, filed Jul. 16, 2015, each of which is incorporated herein by reference in its entirety.

### TECHNICAL FIELD

An organic optoelectronic component is specified. Furthermore, a production method for such an organic optoelectronic component is specified.

### SUMMARY OF THE INVENTION

Embodiments of the invention specify a production method for an organic optoelectronic component with which current paths are efficiently settable.

In accordance with at least one embodiment, the organic optoelectronic component comprises an organic layer sequence. The main function of the component is realized by means of the organic layer sequence. By way of example, the component is an organic light emitting diode, OLED for short, a photodetector or an organic photovoltaic cell, PV cell for short. Accordingly, the organic layer sequence is designed for generating electromagnetic radiation, particularly preferably for generating visible light, or for converting radiation into an electric current or into an electrical signal.

Furthermore, the component is preferably an areal component. This can mean that, as seen in plan view, the organic layer sequence fulfils its function across an area of at least 1 cm² or 10 cm² or 100 cm². By way of example, a light-generating area of the organic layer sequence is then at least 100 cm², as seen in plan view.

In accordance with at least one embodiment, the component comprises a first electrode layer and a second electrode layer. The organic layer sequence is situated between the two electrode layers. A lateral current spreading and a current impressing into the organic layer sequence or a signal impressing from the organic layer sequence into the electrode layers are effected preferably areally via the two electrode layers. At least one of the electrode layers is preferably transmissive to visible light. The organic layer sequence is preferably in direct contact with one of the two electrode layers.

In accordance with at least one embodiment, the optoelectronic component comprises a current confinement layer. The current confinement layer is particularly preferably transmissive to visible light. That is to say that light to be absorbed by the organic layer sequence or generated by the organic layer sequence can pass through the current confinement layer. A transparency of the current confinement layer in a relevant spectral range is preferably at least 90% or 95% or 98%.

In accordance with at least one embodiment, the current confinement layer is situated over the whole area between the first electrode layer and the organic layer sequence. This means that the organic layer sequence is spaced apart and separated from the electrode layer by the current confinement layer. In particular, the first electrode layer and the organic layer sequence do not directly touch one another.

In accordance with at least one embodiment, the current confinement layer directly adjoins both the first electrode layer and the organic layer sequence. A direct contact between the current confinement layer and the first electrode layer and also the organic layer sequence is present in particular over the whole area.

In accordance with at least one embodiment, the current confinement layer comprises continuously a common starting material or material. In other words, the current confinement layer is applied as a continuous, geometrically unstructured layer. No phase boundaries or separating lines caused by application of the starting material for the current confinement layer are evident in the current confinement layer as present in the finished produced component.

In accordance with at least one embodiment, the current confinement layer is produced from such a starting material which is switchable from an electrically conductive to an electrically insulating state, or vice-versa, preferably permanently by treatment with a radiation, in particular with ultraviolet radiation, and/or by action of temperature. By way of example, the starting material of the current confinement layer is chosen in such a way that said starting material is convertible from an electrically insulating state to an electrically conductive state permanently by ultraviolet radiation.

In accordance with at least one embodiment, the current confinement layer comprises at least one conductive region having a high electrical conductivity and at least one insulating region having a low electrical conductivity. The electrical conductivities are set by a material of the current confinement layer itself. That is to say that the electrical conductivities are then not set by layers, such as electrical insulation layers, present in addition to the current confinement layer.

In accordance with at least one embodiment, the electrical conductivities of the conductive region and of the insulating region differ from one another by at least a factor of 10 or 1000 or 100 000. This applies in particular to conductivities in a direction parallel to a surface normal of the organic layer sequence. In other words, a current impressing from the first electrode layer into the organic layer sequence is then possible through the conductive regions, whereas this is prevented or greatly suppressed in the region of the insulating regions. A lateral electrical conductivity, that is to say electrical conductivity present within the main extension directions of the organic layer sequence, is preferably low or negligible, such that boundaries between the conductive region and the insulating region simultaneously constitute energization boundaries for the organic layer sequence. In particular, an electrical conductivity in a lateral direction of the organic layer sequence is also negligible.

According to at least one embodiment, the organic optoelectronic component, which is preferably an organic light emitting diode, comprises a first electrode layer, a second electrode layer and an organic layer sequence situated between the electrode layers. The organic layer sequence is preferably designed for generating visible light. Furthermore, the component comprises a light-transmissive current confinement layer, which is fitted over the whole area between the first electrode layer and the organic layer sequence, such that the organic layer sequence is spaced apart from the first electrode layer. The current confinement layer is produced continuously from a common starting material. The current confinement layer is structured by treatment with a radiation and/or by action of temperature into at least one conductive region having a high electrical conductivity and into at least one insulating region having a low electrical conductivity. The electrical conductivities of the conductive region and of the insulating region differ from one another by at least a factor of 10, preferably at least a factor of 10 000.

In stacked electrical components such as organic light emitting diodes or photovoltaic cells or detectors it is often necessary to structure current flows laterally, such that current flows only in partial regions, as seen in plan view. Such a structuring makes it possible to achieve for example electrical bridges of layers at different electrical potentials through local insulation, for instance in order to define active and/or inactive areas, in particular of the organic layer sequence.

A local confinement of electric current flows is possible for example by means of the structured deposition of insulating and/or electrically conductive layers. During a structured deposition, however, sharp edges and steps generally occur, across which it can be problematic to apply an organic layer sequence, which is usually only a few 100 nm thick. It is likewise possible to perform a whole-area deposition of insulating and/or electrically conductive materials and subsequently to remove these materials again in places. During a removal of material, residues often remain, however, which can impair the reliability of the resulting component.

In the case of the component described here, a whole-area or substantially whole-area current confinement layer is present which is introduced into the electrical layer stack of the component. The current confinement layer is subdivided into electrically insulating and electrically conductive regions, such that a lateral structuring of current flows is made possible by a treatment of the current confinement layer without material removal and without thickness gradations. Such a current confinement layer allows a simplified process implementation during the production of the component and thus in particular a cost saving and an increase in the reliability. Geometrical steps can likewise be omitted in comparison with geometrically structured layers, as a result of which, for instance, mechanical stresses in the layer stack are avoided, or as a result of which separation edges for subsequently applied layers are omitted or reduced.

In accordance with at least one embodiment, the current confinement layer covers the first electrode layer completely, as seen in plan view. In other words, the first electrode layer is not exposed at any point in a direction toward the organic layer sequence.

In accordance with at least one embodiment, the insulating region surrounds a first conductive region and the organic layer sequence in a frame-shaped fashion all around as seen in plan view. In other words, as seen in plan view, the insulating region realizes a circumferential frame around a first conductive region of the current confinement layer and/or around the organic layer sequence.

In accordance with at least one embodiment, the insulating region is surrounded by a second conductive region of the current confinement layer in a frame-shaped fashion all around and preferably completely circumferentially. In other words, the two conductive regions of the current confinement layer are separated from one another by the insulating region, as seen in plan view. Within the current confinement layer, preferably no current flow takes place between the at least two conductive regions.

In accordance with at least one embodiment, at least two or exactly two metallic contact regions are applied on the current confinement layer. The contact regions are designed for electrically contacting the electrode layers. The electrical contact regions are preferably fitted directly on the current confinement layer. The electrical contact regions can comprise one or more metal layers. An area of the contact regions, as seen in plan view, is in each case preferably at most 20% or 10% or 3% or 1% of an area of the first electrode layer. In other words, as seen in plan view, the contact regions constitute a negligible proportion of the area of the entire component.

In accordance with at least one embodiment, at least one first electrical contact region and at least one second electrical contact region are present. The at least one first electrical contact region electrically contacts the first electrode layer, for example, and the at least one second electrical contact region electrically contacts the second electrode layer. If a plurality of contact regions are present, for example a plurality of first contact regions, then they can be arranged around the first electrode layer all around as seen in plan view. The same correspondingly applies to the second contact regions.

In accordance with at least one embodiment, the first contact regions are fitted on the at least one conductive region of the current confinement layer. The second contact regions are situated on an insulating region of the current confinement layer. As a result, it is possible to process all contact regions simultaneously and to prevent short circuits. By way of example, only one first contact region and/or only one second contact region are/is present.

In accordance with at least one embodiment, at least one conductor web is applied in places on one of the electrode layers, in particular on the first electrode layer. The conductor web is formed for example from a light-nontransmissive material such as a metal. Via the one or via the plurality of conductor webs, a lateral current distribution is effected, in particular across the first electrode layer. Such conductor webs are also referred to as busbars.

In accordance with at least one embodiment, the insulating region or one of the insulating regions is situated between the conductor web and the organic layer sequence. As a result, it is possible to prevent a direct current flow from the conductor web into the organic layer sequence from taking place.

In accordance with at least one embodiment, as seen in plan view, at least one insulating region of the current confinement layer is situated within the organic layer sequence. A pictogram, a symbol or lettering is represented by said at least one insulating region. Since the insulating layer is light-transmissive, the pictogram, the symbol or the lettering is visible only in the switched-on state of the component, which is then in particular an organic light emitting diode. In this case, the current confinement layer in the region of the pictogram, symbol or lettering preferably directly adjoins the organic layer sequence and the first electrode layer.

In accordance with at least one embodiment, the organic layer sequence projects beyond the first electrode layer all around as seen in plan view. As an alternative thereto, it is possible for the organic layer sequence and the first electrode layer to extend congruently or approximately congruently with respect to one another. Alternatively, it is also possible for the first electrode layer to project beyond the organic layer sequence all around, as seen in plan view.

In accordance with at least one embodiment, the insulating region or one of the insulating regions covers an outer edge of the first electrode layer all around, as seen in plan view. The insulating region can be delimited to the outer edge of the first electrode layer, for example with a tolerance of at most 10% or 5% or 2% of a mean diameter of the organic layer sequence, as seen in plan view.

In accordance with at least one embodiment, one of a plurality of conductive regions of the current confinement layer is surrounded all around by the insulating region or by one of the insulating regions. In this case, it is possible that, as seen in plan view, the conductive region surrounded by the insulating region is completely encompassed by the first electrode layer and/or that the first electrode layer projects beyond this insulating region all around.

In accordance with at least one embodiment, the first electrode layer is fashioned such that it is light-transmissive. In particular, the first electrode layer is then produced from an electrically conductive metal oxide, in particular comprising indium, tin and/or zinc. It is possible for a thickness of the first electrode layer then to be at least 25 nm or 50 nm or 100 nm and/or at most 500 nm or 250 nm or 150 nm.

In accordance with at least one embodiment, the second electrode layer is a mirror layer. In this case, the second electrode layer is preferably a metallic layer or a metallic layer stack.

In accordance with at least one embodiment, the first electrode layer is fashioned such that it is reflective and light-nontransmissive and thus as a mirror. In this case, the second electrode layer is light-transmissive. As an alternative thereto, it is also possible for both electrode layers to be light-transmissive. In the last-mentioned case, the component can be an organic light emitting diode which emits on both sides and/or a transparent organic light emitting diode.

In accordance with at least one embodiment, the component comprises a carrier. The carrier can be the component part which mechanically carries and supports the component. The carrier can be mechanically rigid or else mechanically flexible, such that, in the last-mentioned case, the component can bend without being destroyed during operation as intended. By way of example, the carrier is a glass plate, a glass film, a plastic plate, a plastic film, a ceramic plate or a metal film.

In accordance with at least one embodiment, a planarization layer is situated directly on the carrier. At a side facing away from the carrier the planarization layer has a lower surface roughness than the carrier. By way of example, the surface roughness of the planarization layer at the side facing away from the carrier is at most 50 nm or 20 nm. The surface roughness is also designated as Ra.

In accordance with at least one embodiment, the first electrode layer is situated directly at a side of the planarization layer facing away from the carrier. In this case, the first electrode layer can cover the planarization layer only partly or else completely or laterally project beyond the planarization layer.

In accordance with at least one embodiment, the current confinement layer is produced from a single and homogenous layer. That is to say that directly after the application of the current confinement layer the latter is a single, continuous layer composed of preferably just a single starting material. The current confinement layer preferably has a constant or approximately constant thickness across the entire region in which the current confinement layer is applied. This preferably applies both to the material being applied precisely for the current confinement layer and to the finished current confinement layer.

In accordance with at least one embodiment, the current confinement layer is an inorganic layer. In this case, the current confinement layer is preferably formed from a metal oxide and/or a metal oxide ceramic or from mixtures thereof.

In accordance with at least one embodiment, the current confinement layer has a thickness of at least 4 nm or 12 nm or 30 nm or 50 nm or 100 nm. Alternatively or additionally, the thickness of the current confinement layer is at most 10 μm or 5 μm or 1 μm or 0.5 μm or 0.3 μM.

In accordance with at least one embodiment, the electrical conductivity in the insulating region, in particular in a direction parallel to a surface normal of the organic layer sequence, is at most 1 μS/m or 1 mS/m or 1 S/m. As a result, it is possible for a current flow into the organic layer sequence through the insulating region to be reduced to an extent such that no or no significant light generation takes place in the organic layer sequence, particularly if the component is an organic light emitting diode.

In accordance with at least one embodiment, the current confinement layer is produced from the material 12 CaO.7 Al₂O₃. This material and a setting of the electrical conductivity of this material in particular by ultraviolet radiation are described in the document Hayashi et al. in Nature 419, pages 462 to 465, October 2002. The disclosure content of said document with regard to the material mentioned and the processing of this material is incorporated by reference.

In accordance with at least one embodiment, the current confinement layer is produced from an organic material. By way of example, the current confinement layer is then a layer composed of one or more polymers. The at least one polymer is for example a conjugated polymer and/or a homonuclear or heteronuclear polymer, in particular a dihydropyrene, for example [2.2]metacyclophanes, (dimethyl)dihydrophenanthrene or [2.2]metacyclophanediene. Such materials are specified for instance in the document Tyutyulkov et al. in the article “Photoswitching of the Optical and Electrical Properties of One-dimensional π-Electron Systems” in Z. Naturforsch., Vol. 57 a, pages 89 to 93, from 2002. The disclosure content of said document with regard to suitable polymers is incorporated by reference.

Furthermore, a production method for an organic optoelectronic component is specified. In this case, the component produced by the production method is fashioned as described in conjunction with one or more of the embodiments mentioned above. Therefore, features of the production method are also disclosed for the organic optoelectronic component, and vice-versa.

According to at least one embodiment, the production method comprises the following steps:

A) providing a carrier,
B) applying a first electrode layer to the carrier,
C) applying a current confinement layer to the first electrode layer in a geometrically unstructured fashion,
D) applying an organic layer sequence to the current confinement layer,
E) applying a second electrode layer to the organic layer sequence, and
F) structuring the current confinement layer without material removal by means of irradiation and/or action of heat permanently into at least one conductive region having a high electrical conductivity and into at least one insulating region having a low electrical conductivity, wherein the electrical conductivities of the conductive region and of the insulating region differ from one another by at least a factor of 10.

In accordance with at least one embodiment, the current confinement layer is electrically insulating directly after step C). That is to say that directly after step C), the current confinement layer then still consists of a single insulating region.

In accordance with at least one embodiment, step F) is carried out between steps C) and D). In particular, step F) is then carried out by means of irradiation, for instance with ultraviolet radiation, with the aid of a shadow mask.

In accordance with at least one embodiment, the material of the current confinement layer is switchable at least once with regard to the electrical conductivity by means of ultraviolet radiation. In this case, this switching is preferably possible only with radiation having such wavelengths which are not generated during intended operation of the organic light emitting diode. Furthermore, it is possible for the component to contain a filter layer which prevents radiation having wavelengths suitable for switching the electrical conductivity of the current confinement layer from passing to the current confinement layer from outside the component. By way of example, a filter layer which prevents ultraviolet radiation from sunlight, for instance, from passing to the current confinement layer is then fitted to the component.

### BRIEF DESCRIPTION OF THE DRAWINGS

A component described here and a production method described here are explained in greater detail below on the basis of exemplary embodiments with reference to the drawing. In this case, identical reference signs indicate identical elements in the individual figures. In this case, however, relations to scale are not illustrated; rather, individual elements may be illustrated with exaggerated size in order to afford a better understanding.

In the figures:

FIGS. 1 to 6 show exploded drawings of sectional illustrations of exemplary embodiments of organic optoelectronic components described here, and

FIG. 7 shows method steps for a production method for an organic optoelectronic component described here in sectional illustrations.

### DETAILED DESCRIPTION OF ILLUSTRATIVE EMBODIMENTS

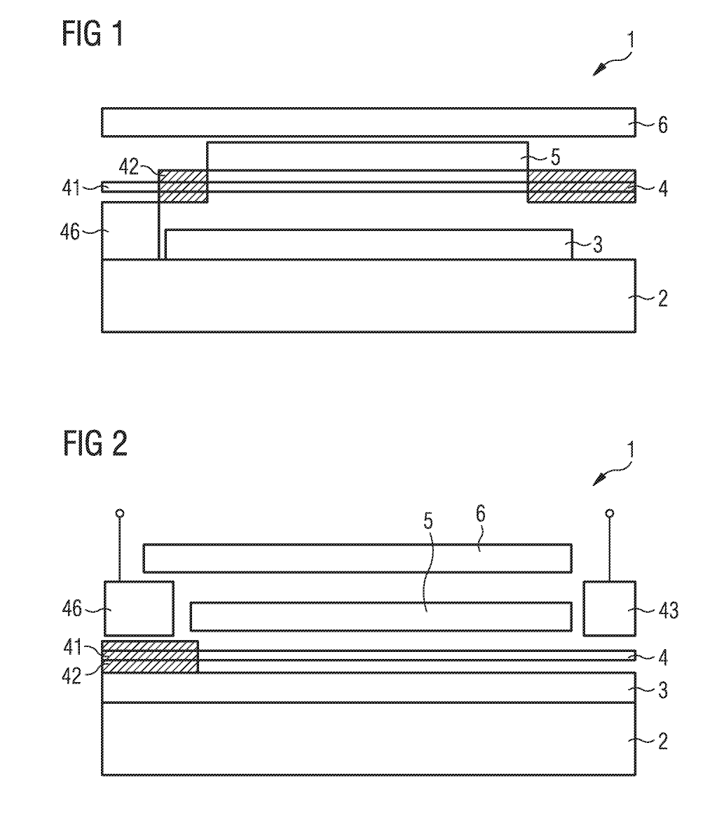

FIG. 1 shows one exemplary embodiment of an organic optoelectronic component 1. The component 1 comprises a radiation-transmissive carrier 2, for example a glass plate. A first electrode layer 3 is applied on the carrier 2. The first electrode layer 3 is produced for example from indium tin oxide, ITO for short, and is light-transmissive. Furthermore, an electrical contact region 46 is situated at the carrier 2. The electrical contact region 46 is preferably composed of three metallic layers composed, for instance, of chromium, aluminum and again chromium.

A current confinement layer 4 is applied over the whole area on the carrier 2. The current confinement layer 4 comprises two conductive regions 41, which are electrically conductive. Furthermore, the current confinement layer 4 comprises an insulating region 42, which is electrically insulating. In FIGS. 1 to 6, the insulating regions 42 are illustrated symbolically in each case in a manner bordered by a box. The current confinement layer 4 has a constant thickness in the lateral direction, that is to say in a direction parallel to a main side of the carrier 2. In particular, the conductive regions 41 and the insulating regions 42 are of identical thickness.

An organic layer sequence 5 is applied above the first electrode layer 3 and on the current confinement layer 4 in a central conductive region 41. The organic layer sequence 5 is preferably designed to generate visible light during the operation of the component 1. The component 1 is then an OLED. The generated light emerges from the component 1 through the first electrode layer 3 and through the carrier 2.

Finally, a second electrode layer 6 is shown as the topmost layer illustrated in FIG. 1. The second electrode layer 6 is preferably a mirror layer for the light generated in the organic layer sequence 5. The second electrode layer 6 is furthermore preferably a metal layer or a layer stack composed of a plurality of metal plies.

Other component parts of the organic light emitting diode 1, such as electrical connection lines or encapsulations, are respectively not depicted for the sake of simplifying the illustration. Moreover, the organic layer sequence 5 is illustrated only in a simplified manner; in particular, partial layers such as charge carrier generating layers, charge carrier barrier layers and active zones are not depicted.

The current confinement layer 4 is applied in a geometrically unstructured fashion across the entire carrier 2 or across at least 90% of the carrier 2. The subdivision into the conductive regions 41 and the insulating region 42 takes place only after the actual application of the current confinement layer 4 by means of an exposure method or by means of a heating method. By means of the exposure or the thermal treatment the electrical conductivity of a material of the current confinement layer 4 can be permanently set, without a material of the current confinement layer 4 having to be removed. In particular, the current confinement layer 4 is produced from 12 CaO.7 Al₂O₃.

As seen in plan view, the inner conductive region 41 is situated congruently below the organic layer sequence 5. Said inner conductive region 41 and also the organic layer sequence 5 are surrounded by the insulating region 42 in a frame-shaped fashion all around. In this case, the insulating region 42 extends across edges of the first electrode layer 3. This prevents the second electrode layer 6 from coming into direct electrical contact with the first electrode layer 3. The second electrode layer 6 is externally electrically contactable via the electrical contact region 46. A corresponding electrical contact region for the first electrode layer 3 is not depicted in FIG. 1.

The current confinement layer 4 is light-transmissive both in the conductive regions 41 and in the continuous insulating region 42. The optical properties of the conductive regions 41 and of the insulating region 42 do not differ or do not differ significantly from one another.

FIG. 2 shows a further exemplary embodiment of the component 1, which is once again fashioned as an organic light emitting diode. In contrast to FIG. 1, the current confinement layer 4 is applied over the whole area directly on the first electrode layer 3. As a result, the electrical contact regions 43, 46 are situated at a side of the current confinement layer 4 facing away from the carrier 2. The electrical contact region 46, which is fashioned for example as a cathode and via which the second electrode layer 6 is externally electrically contactable, is situated on the insulating region 42. Consequently, the electrical contact region 46 is electrically insulated from the first electrode layer 3 by the insulating region 42. The first electrode layer 3 is electrically directly connected to the electrical contact region 43 through the conductive region 41.

In other words, the insulating region 42, as seen in plan view, can be delimited to the electrical contact region or electrical contact regions 46. In this case, it is possible for the organic layer sequence 5 and the insulating region 42 to overlap one another in the region of the electrical contact region 46 as seen in plan view. Furthermore, the insulating region 42 is fashioned in such a way that there is no direct electrical contact between the two electrode layers 3, 6.

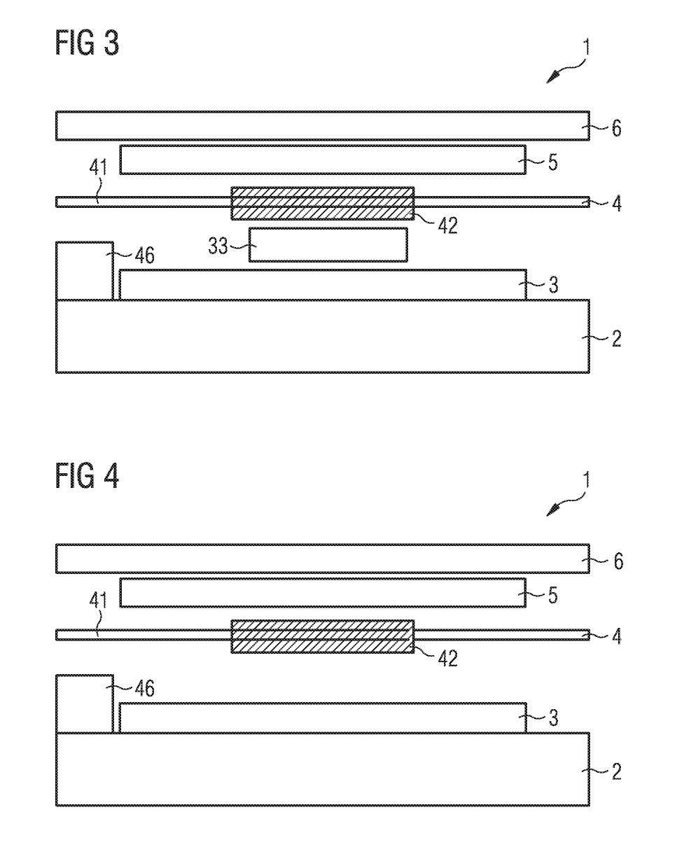

In the exemplary embodiment as shown in FIG. 3, a conductor web 33 is situated on the first electrode layer 3. The conductor web 33 is fashioned from a metallic material, for example, and is thus light-nontransmissive. In order to prevent a generation of light in the organic layer sequence 5 directly above the conductor web 33, the insulating region 42 is fitted between the conductor web 33 and the organic layer sequence 5. Consequently, no direct current flow takes place between the conductor web 33 and the organic layer sequence 5. In this case, preferably, side surfaces of the conductor web 33 are also covered by the insulating region 42. By means of such a conductor web 33, a lateral current spreading can be realized across the entire first electrode layer 3, such that a more uniform current impressing into the organic layer sequence 5 can be realized, and hence a more uniform light generation.

Unlike in the illustration in FIG. 3, further insulating regions 42 can also be present which act analogously to FIG. 1 or FIG. 2.

In the exemplary embodiment in FIG. 4, the insulating region 42 is situated between the first electrode layer 3 and the organic layer sequence 5, said insulating region directly adjoining the organic layer sequence 5 and the first electrode layer 3 over the whole area. As seen in plan view, the insulating region 42 has the shape of a pictogram, of a symbol or of lettering. Said pictogram, symbol or lettering is then discernible only in the switched-on state of the component 1 since, in the region of the insulating region 42, no light is generated in the organic layer sequence 5, but in the switched-off state the insulating region 42 is optically indistinguishable from the conductive region 41 for an observer.

As also in FIGS. 1 to 3, in accordance with FIG. 4, light is coupled out exclusively through the carrier 2 and through the first electrode layer 3. The second electrode layer 6 is embodied in each case as a mirror layer. As an alternative thereto, it is possible for the second electrode layer 6 also to be fashioned such that it is light-transmissive, with the result that the component 1 can then be fashioned such that it is radiation-transmissive and light emitting on both sides.

In accordance with FIG. 5, too, a symbol, lettering or pictogram is realized by the insulating region 42. Unlike in the illustration in FIG. 4, the first electrode layer 3 is fashioned such that it is light-nontransmissive and specularly reflective, and the second electrode layer 6 is a light-transmissive electrode.

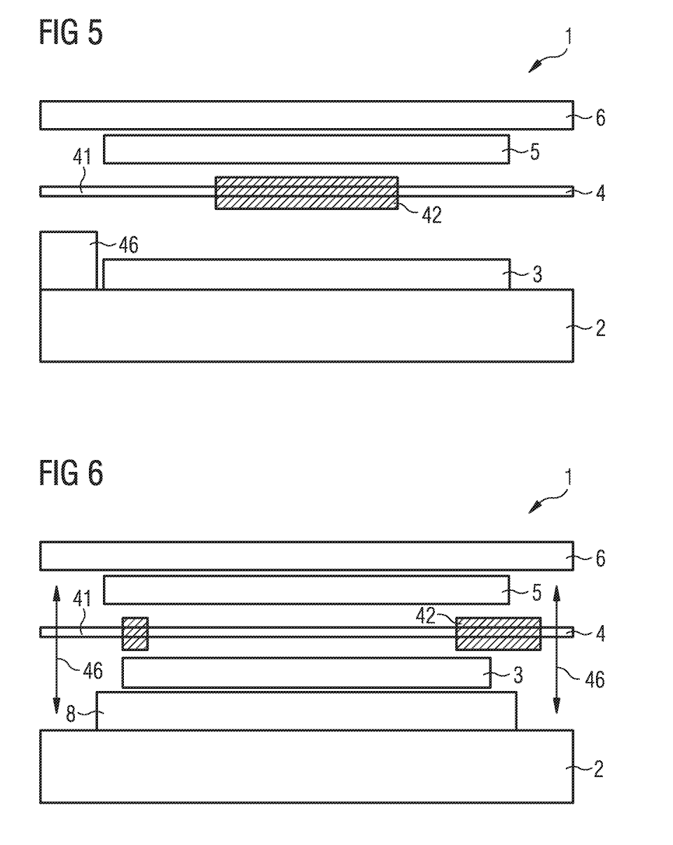

In the exemplary embodiment in FIG. 6, a planarization layer 8 is situated between the first electrode layer 3 and the carrier 2. Preferably, the planarization layer 8 is electrically insulating and the first electrode layer 3 is reflective. The second electrode layer 6 is then a radiation-transmissive, transparent electrode.

The insulating region 42 is applied in a frame-shaped fashion all around on an outer edge of the first electrode layer 3. In this case, a further conductive region 41 lies outside this frame composed of the insulating region 42. Through this outer conductive region 41 an electrical connection between the second electrode layer 6 and the carrier 2 is possible, symbolized by the double-headed arrows 46 in FIG. 6. As a result, the then preferably electrically conductive carrier 2 or carrier 2 provided with conductor tracks can serve as an electrical contact region 46 for at least the second electrode layer 6.

The possibilities for the use of the conductive regions 41 and the insulating regions 42 as shown in FIGS. 1 to 6 can also be combined with one another in each case. In this regard, in particular, an insulating possibility or electrically conductive connection of the contact regions 43, 46 can be combined with a representation of pictograms, symbols or letterings and furthermore alternatively or additionally with conductor webs.

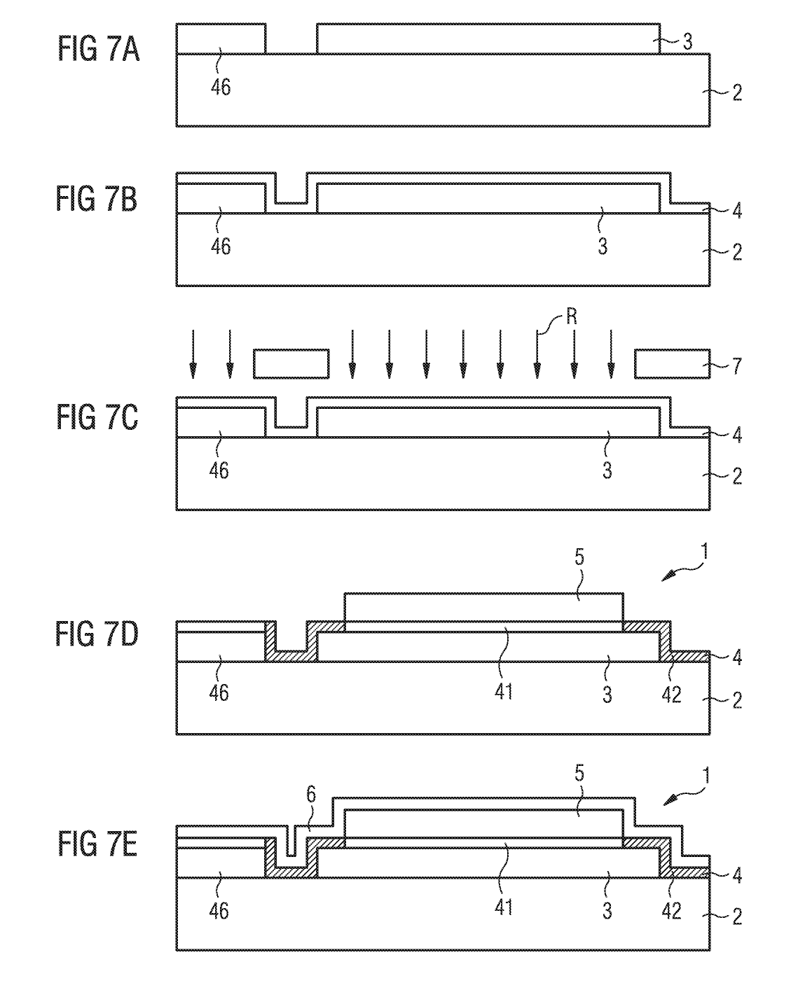

FIG. 7 schematically illustrates a production method for the component 1. In accordance with FIG. 7A, the carrier 2 with the first electrode layer 3 and, for instance, the electrical contact region 46 is provided.

FIG. 7B reveals that the current confinement layer 4 is applied over the whole area. Directly after application, the current confinement layer 4 is electrically insulating and of the same thickness for example over the whole area.

In the subsequent step, see FIG. 7C, a shadow mask 7 is provided. The current confinement layer 4 is exposed in places by means of ultraviolet radiation R. The exposed regions then form the conductive regions 41; the unexposed regions remain electrically insulating and constitute the insulating regions 42.

In a departure from the illustration in FIG. 7C, the conversion of the originally applied current confinement layer 4 into the conductive regions 41 and the insulating regions 42 can also be carried out by means of the action of temperature.

In accordance with FIG. 7D, the organic layer sequence 5 is applied above the inner conductive region 41. Finally, see FIG. 7E, the second electrode layer 6 is produced. The finished component 1 is then fashioned in particular as shown in conjunction with FIG. 1.

Since the conductive regions 41 are generated by the radiation R, preferably no radiation R which is suitable for converting the insulating regions 42 into the conductive region 41 is generated during the operation of the finished component 1. As also in all the other exemplary embodiments, it is possible for a filter layer (not illustrated) to be present which, in the finished component 1, prevents radiation suitable for converting the insulating regions 42 into the conductive region 41 from passing to the current confinement layer 4.

The invention described here is not restricted by the description on the basis of the exemplary embodiments. Rather, the invention encompasses any novel feature and also any combination of features, which in particular includes any combination of features in the patent claims, even if this feature or this combination itself is not explicitly specified in the patent claims or exemplary embodiments.

1-14. (canceled)

15. An organic optoelectronic component comprising:
a first electrode layer;
a second electrode layer;
an organic layer sequence located between the first electrode layer and the second electrode layer; and
a light-transmissive current confinement layer located over the entire area between the first electrode layer and the organic layer sequence, such that the organic layer sequence is spaced apart from the first electrode layer;
wherein the current confinement layer is structured into a conductive region having a high electrical conductivity and into an insulating region having a low electrical conductivity, the high electrical conductivity differing from the low electrical conductivity by at least a factor of 10, the current confinement layer being produced continuously from a common starting material and being structured by treatment with a radiation and/or by action of temperature.

16. The organic optoelectronic component according to claim 15, wherein the organic optoelectronic component is an organic light emitting diode;
wherein the organic layer sequence is designed for generating visible light; and
wherein, as seen in plan view, the current confinement layer completely covers the first electrode layer, the insulating region surrounds a first conductive region and the organic layer sequence in a ring-shaped fashion, and the insulating region is surrounded by a second conductive region all around in a ring-shaped fashion.

17. The organic optoelectronic component according to claim 15, further comprising a plurality of metallic, electrical contact regions for electrically contacting the first and second electrode layers directly applied on the current confinement layer; and
wherein the insulating region is located between only one of the contact regions and the first electrode layer and wherein another one of the contact regions is applied on the conductive region.

18. The organic optoelectronic component according to claim 15, further comprising a light-nontransmissive conductor web for lateral current distribution applied in places on the first electrode layer, wherein the insulating region is located between the conductor web and the organic layer sequence.

19. The organic optoelectronic component according to claim 15, wherein the current confinement layer areally directly adjoins the first electrode layer and the organic layer sequence; and
wherein, as seen in plan view, the insulating region is located within the organic layer sequence and forms a pictogram that is visible only in a switched-on state of the component.

20. The organic optoelectronic component according to claim 15, wherein, as seen in plan view, the organic layer sequence projects beyond the first electrode layer all around, the insulating region covers an outer edge of the first electrode layer all around in a ring-shaped fashion, and one of a plurality of conductive regions is surrounded by the insulating region in a ring-shaped fashion and is completely encompassed by the first electrode layer.

21. The organic optoelectronic component according to claim 15, wherein the first electrode layer is light-transmissive and wherein the second electrode layer is a mirror layer for light generated during operation of the component.

22. The organic optoelectronic component according to claim 21, wherein the first electrode layer is composed of an electrically conductive metal and has a thickness of between 25 nm and 500 nm inclusive.

23. The organic optoelectronic component according to claim 22, wherein the first electrode layer is composed of an electrically conductive metal oxide selected from the group consisting of In, Sn and Zn.

24. The organic optoelectronic component according to claim 15, wherein the first electrode layer is reflective and light-nontransmissive, and the second electrode layer is light-transmissive.

25. The organic optoelectronic component according to claim 15, further comprising:
a carrier that mechanically supports the component; and
a planarization layer located directly on the carrier and, at a side facing away from the carrier, has a smaller surface roughness than the carrier, wherein the first electrode layer is applied directly on the planarization layer.

26. The organic optoelectronic component according to claim 15, wherein the current confinement layer is composed of a metal oxide or a metal oxide ceramic having a thickness of between 0.03 μm and 0.5 μm inclusive, wherein the low electrical conductivity is at most 1 mS/m.

27. The organic optoelectronic component according to claim 15, wherein the current confinement layer is composed of 12 CaO.7 Al₂O₃.

28. The organic optoelectronic component according to claim 15, wherein the current confinement layer is produced from one or more polymers.

29. A method for making an organic optoelectronic component, the method comprising:
providing a carrier;
applying a first electrode layer to the carrier;
applying a current confinement layer to the first electrode layer in a geometrically unstructured fashion;
applying an organic layer sequence to the current confinement layer;
applying a second electrode layer to the organic layer sequence; and
structuring the current confinement layer without material removal by means of irradiation and/or action of heat so that the current confinement layer permanently includes a conductive region having a high electrical conductivity and an insulating region having a low electrical conductivity, wherein the high and low electrical conductivities differ from one another by at least a factor of 10.

30. The method according to claim 29, wherein the current confinement layer is electrically insulating directly after being applied to the first electrode layer.

31. The method according to claim 29, wherein the current confinement layer is structured before applying the organic layer sequence.

32. The method according to claim 31, wherein the current confinement layer is structured using irradiation with the aid of a shadow mask.

33. An organic optoelectronic component comprising:
a first electrode layer;
a second electrode layer;
an organic layer sequence located between the first electrode layer and the second electrode layer; and
a light-transmissive current confinement layer located over the entire area between the first electrode layer and the organic layer sequence, such that the organic layer sequence is spaced apart from the first electrode layer;
wherein the current confinement layer is produced continuously with a constant thickness from a single common starting material;
wherein the current confinement layer is structured into a plurality of conductive regions having a high electrical conductivity and into at least one insulating region having a low electrical conductivity, the electrical conductivities of the conductive regions and of the insulating region differing from one another by at least a factor of 10;
wherein the organic layer sequence projects beyond the first electrode layer all around;
wherein the insulating region covers an outer edge of the first electrode layer all around in a ring-shaped fashion; and
wherein at least one of the conductive regions is surrounded by the insulating region in a ring-shaped fashion and is completely encompassed by the first electrode layer.
